(19) United States
(12) Patent Application Publication
(10) Pub. No.: US 2006/0220124 A1
(43) Pub. Date: Oct. 5, 2006

(54) Semiconductor device and fabrication method of the same

(75) Inventor: Fumio Ohtake, Yokohama (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: EUDYNA DEVICES, INC., Yamanashi (JP)

(21) Appl. No.: 11/392,666

(22) Filed: Mar. 30, 2006

(30) Foreign Application Priority Data
Mar. 31, 2005 (JP) 2005-105162

(51) Int. Cl. H01L 29/76

(52) U.S. Cl. 257/344

(57) ABSTRACT

A semiconductor device includes a gate electrode, a source electrode, a drain electrode and an electrode part. The gate electrode is formed above a semiconductor layer. The source electrode and the drain electrode are formed on the semiconductor layer. The gate electrode is located between the source electrode and the drain electrode. The electrode part is provided between the gate electrode and the drain electrode and has a width of 10 nm to 300 nm in a direction between the gate electrode and the drain electrode.

### BACKGROUND OF THE INVENTION

1. Field of the Invention

This invention generally relates to a semiconductor device and a fabrication method of the same.

2. Description of the Related Art

Conventionally, a field effect transistor has been known as a semiconductor device including such as a microwave, a quasi-milliwave or a milliwave which are suitable for amplifying in a high-frequency band. An attempt to provide a screening electrode or a source wall in an offset region of the field-effected transistor has been made for the purpose of improving a drain breakdown voltage and reducing electric capacitance between a gate and a drain.

Japanese Patent Application Publication No. 2002-343960 (hereinafter referred to as Document 1) discloses, for example, an art in which a screening conducting layer is provided in the offset region. According to the art, it is possible to reduce on-resistance with the drain breakdown voltage being kept high. And, Japanese Patent Application Publication No. 2002-110700 (hereinafter referred to as Document 2) discloses an art in which the source wall is provided between the gate and the drain. According to the art, it is possible to improve high-frequency property with a parasitic capacitance between the gate and the drain being reduced.

The screening electrode or the source wall causes, however, reducing a drain current, because the screening electrode and the source wall are generally connected to a ground potential. Accordingly, in a case where the art of the Document 1 or the Document 2 are used, the drain breakdown voltage is improved but the drain current is reduced.

### SUMMARY OF THE INVENTION

The present invention has an object to provide a semiconductor device in which the drain current is not reduced and the drain breakdown voltage is improved.

According to an aspect of the present invention, preferably, there is provided a semiconductor device including a gate electrode, a source electrode, a drain electrode and an electrode part. The gate electrode is formed above a semiconductor layer. The source electrode and the drain electrode are formed on the semiconductor layer. The gate electrode is located between the source electrode and the drain electrode. The electrode part is provided between the gate electrode and the drain electrode and has a width of 10 nm to 300 nm in a direction between the gate electrode and the drain electrode.

In accordance with the semiconductor device of the present invention, the electrode is formed between the gate electrode and the drain electrode. And the drain breakdown voltage is improved. In addition, the electrode part has a small width in the direction between the gate electrode and the drain electrode. And it is possible to restrain the reduction of the drain current. It is, therefore, possible to improve the drain breakdown voltage and to restrain the reduction of the drain current in the semiconductor device in accordance with the present invention.

According to another aspect of the present invention, preferably, there is provided a semiconductor device including a gate electrode, a source electrode, a drain electrode and a source wall. The gate electrode is formed above a semiconductor layer. The source electrode and the drain electrode are formed on the semiconductor layer. The gate electrode is located between the source electrode and the drain electrode. The source wall extends from the source electrode to between the gate electrode and the drain electrode, passing above the gate electrode. The source wall includes an end part having a width of 10 nm to 300 nm in a direction between the gate electrode and the drain electrode.

In accordance with another semiconductor device of the present invention, the source wall is formed between the gate electrode and the drain electrode. And the drain breakdown voltage is improved. In addition, the width of the end part of the source wall in the direction between the gate electrode and the drain electrode is small. And it is possible to restrain the reduction of the drain current. It is, therefore, possible to restrain the reduction of the drain current and to improve the drain breakdown voltage in the semiconductor device in accordance with the present invention. In addition, high-frequency property of the semiconductor device is improved, because the source wall is provided.

According to still another aspect of the present invention, preferably, there is provided a semiconductor device including a gate electrode, a source electrode, a drain electrode, and a source wall. The gate electrode is formed above a semiconductor layer. The source electrode and the drain electrode are formed on the semiconductor layer. The gate electrode is located between the source electrode and the drain electrode. The electrode part is provided between the gate electrode and the drain electrode, extends in a gate width direction, and has comb teeth extending toward the semiconductor layer.

In accordance with still another semiconductor device of the present invention, the end part of the electrode part has comb teeth lying in the direction in which the gate electrode extends and extending toward the semiconductor layer. And an offset region between the gate electrode and the drain electrode is biased. The drain breakdown voltage of the semiconductor device in accordance with the present invention is, therefore, improved. In addition, there is no electrode between each of the comb teeth. It is, therefore, possible to restrain the reduction of the drain current effectively.

According to still another aspect of the present invention, there is provided a semiconductor device including a gate electrode, a source electrode, a drain electrode and a source wall. The gate electrode is formed above a semiconductor layer. The source electrode and the drain electrode are formed on the semiconductor layer. The gate electrode is located between the source electrode and the drain electrode. The source wall extends from the source electrode to between the gate electrode and the drain electrode, passing above the gate electrode. The source wall has an end part that extends in a gate width direction, and has comb teeth extending toward the semiconductor layer.

In accordance with still another semiconductor device of the present invention, the source wall extends to between the gate electrode and the drain electrode. And an offset region between the gate electrode and the drain electrode is biased. The drain breakdown voltage of the semiconductor device in accordance with the present invention is, therefore, improved. In addition, there is no electrode between each of the comb teeth. And it is possible to restrain the reduction of the drain current of the semiconductor device in accordance with the present invention effectively. Further, the source wall is provided. And high-frequency property of the semiconductor device is improved.

According to an aspect of the present invention, there is provided a fabrication method of a semiconductor device including forming a gate electrode above a semiconductor layer so as to be interposed between a source region and a drain region of the semiconductor layer, forming an insulating layer covering the semiconductor layer and the gate electrode, and forming an electrode part on the insulating layer between the drain region and the gate electrode and the electrode part has a width of 10 nm to 300 nm in a direction between the gate electrode and the drain region.

In accordance with the fabrication method of a semiconductor device of the present invention, the gate electrode is formed between the source region and the drain region. The insulating layer covering the semiconductor layer and the gate electrode is formed. The electrode part that has the width of 10 nm to 300 nm in the direction between the gate electrode and the drain electrode is formed on the insulating layer between the gate electrode and the drain region. In this case, the electrode part is between the gate electrode and the drain region. And the drain breakdown voltage is improved. In addition, the electrode part has a small width in the direction between the gate electrode and the drain electrode. And it is possible to restrain the reduction of the drain current. It is, therefore, possible to restrain the reduction of the drain current and to improve the drain breakdown voltage in the semiconductor device in accordance with the present invention.

According to another aspect of the present invention, preferably, there is provided a fabrication method of a semiconductor device including forming a gate electrode above a semiconductor layer so as to be interposed between a source region and a drain region of the semiconductor layer, forming an insulating layer covering the semiconductor layer and the gate electrode, exposing the source region, and forming a source wall so that the source wall extends from the source region to between the gate electrode and the drain region passing above the gate electrode, and the source wall includes an end part having a width of 10 nm to 300 nm in a direction between the gate electrode and the drain region.

In accordance with another fabrication method of a semiconductor device of the present invention, the gate electrode is formed between the source region and the drain region. The insulating layer covering the semiconductor layer and the gate electrode is formed. The source region is exposed. The source wall that extends from the source region to between the gate electrode and the drain region passing above the gate electrode and has the end part having the width of 10 nm to 300 nm in the direction between the gate electrode and the drain region is formed. In this case, the source wall is provided between the gate electrode and the drain region. And the drain breakdown voltage is improved. In addition, the width of the end part of the source wall in the direction between the gate electrode and the drain region is small. And it is possible to restrain the reduction of the drain current. It is, therefore, possible to restrain the reduction of the drain current and to improve the drain breakdown voltage in the semiconductor device in accordance with the present invention. In addition, the source wall is provided. And high-frequency property of the semiconductor device is improved.

According to still another aspect of the present invention, preferably, there is provided a fabrication method of a semiconductor device including forming a gate electrode above a semiconductor layer so as to be interposed between a source region and a drain region of the semiconductor layer, forming an insulating layer covering the semiconductor layer and the gate electrode, forming an electrode part on the insulating layer between the drain region and the gate electrode. The electrode part has an end part that extends in a direction in which the gate electrode extends, and has comb teeth extending toward the semiconductor layer.

In accordance with still another fabrication method of a semiconductor device of the present invention, the gate electrode is formed between the source region and the drain region. The insulating layer covering the semiconductor layer and the gate electrode is formed. The electrode part that has the comb teeth lying in the direction in which the gate electrode extends and extending toward the semiconductor layer is formed between the gate electrode and the drain region. In this case, an offset region between the gate electrode and the drain region is biased. The drain breakdown voltage of the semiconductor device in accordance with the present invention is improved. In addition, there is no electrode between each of the comb teeth. And it is possible to effectively restrain the reduction of the drain current of the semiconductor device in accordance with the present invention.

According to still another aspect of the present invention, preferably, there is provided a fabrication method of a semiconductor device including forming a gate electrode above a semiconductor layer so as to be interposed between a source region and a drain region of the semiconductor layer, forming an insulating layer covering the semiconductor layer and the gate electrode, exposing the source region, and forming a source wall so that the source wall extends from the source region to between the gate electrode and the drain region, passing above the gate electrode, and the source wall has an end part that extends in a direction in which the gate electrode extends, and has comb teeth extending toward the semiconductor layer.

In accordance with still another fabrication method of a semiconductor device of the present invention, the gate electrode is formed between the source region and the drain region. The insulating layer covering the semiconductor layer and the gate electrode is formed. The source region is exposed. The source wall that has the end part extending in the direction in which the gate electrode extends and having comb teeth extending toward the semiconductor layer is formed from the source region to between the gate electrode and the drain region passing above the gate electrode. In this case, an offset region between the gate electrode and the drain region is biased. Therefore, the drain breakdown voltage of the semiconductor device in accordance with the present invention is improved. In addition, there is no electrode between each of the comb teeth. And it is possible to effectively restrain the reduction of the drain current of the semiconductor device in accordance with the present invention. Further, the source wall is provided. And high-frequency property of the semiconductor device is improved.

### BRIEF DESCRIPTION OF THE DRAWINGS

Preferred embodiments of the present invention will be described in detail with reference to the following drawings, wherein:

FIG. 1 illustrates a partly-omitted perspective view of a semiconductor device in accordance with a first embodiment;

FIG. 2 illustrates a relationship between the gate voltage and the drain current;

FIG. 3 illustrates a circuit diagram to account for the effect of the screening electrode referring to a MOS transistor;

FIG. 4 illustrates a partly omitted schematic cross regional view of the semiconductor device;

FIG. 5 illustrates a relationship between the width of the screening electrode and the drain current;

FIG. 6A through FIG. 6C illustrate a process flow diagram accounting for the fabrication method of the semiconductor device in accordance with the first embodiment;

FIG. 7A through FIG. 7C illustrate a process flow diagram accounting for the fabrication method of the semiconductor device in accordance with the first embodiment;

FIG. 8A through FIG. 8C illustrate a process flow diagram accounting for the fabrication method of the semiconductor device in accordance with the first embodiment;

FIG. 9 illustrates a partly omitted perspective view of a semiconductor device in accordance with a second embodiment;

FIG. 10A through FIG. 10C illustrate a process flow diagram to account for the fabrication method of the semiconductor device in accordance with the second embodiment;

FIG. 11A and FIG. 11B illustrate a process flow diagram to account for the fabrication method of the semiconductor device in accordance with the second embodiment;

FIG. 12A through FIG. 12C illustrate a semiconductor device in accordance with a third embodiment;

FIG. 13A through FIG. 13C illustrate a process flow diagram to account for the fabrication method of the semiconductor device in accordance with the third embodiment;

FIG. 14A and FIG. 14B illustrate a process flow diagram to account for the fabrication method of the semiconductor device in accordance with the third embodiment;

FIG. 15A through FIG. 15C illustrate a semiconductor device in accordance with a fourth embodiment;

FIG. 16A through FIG. 16C illustrate a process flow diagram to account for the fabrication method of the semiconductor device in accordance with the fourth embodiment; and

FIG. 17A and FIG. 17B illustrate a process flow diagram to account for the fabrication method of the semiconductor device in accordance with the fourth embodiment.

### DESCRIPTION OF THE PREFERRED EMBODIMENTS

A description will now be given with reference to the accompanying drawings, of embodiments of a semiconductor device and a fabrication method of the same in accordance with the present invention.

### First Embodiment

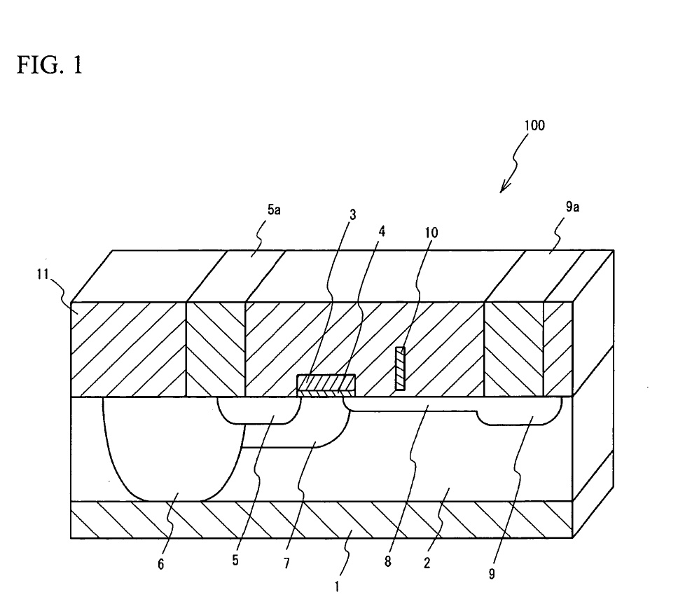

FIG. 1 illustrates a partly-omitted perspective view of a semiconductor device 100 in accordance with a first embodiment. As shown in FIG. 1, the semiconductor device 100 has a low-resistance P++ type substrate 1, a high-resistance P− type epitaxial layer 2, a gate electrode 3, a gate oxide film 4, a source region 5, a source electrode 5a, a penetrating conductive region 6, a channel region 7, an offset region 8, a drain region 9, a drain electrode 9a, a screening electrode 10 and an insulating film 11.

The low-resistance P++ type substrate 1 is, for example, composed of a low-resistance P++ type monocrystalline-silicon which includes a high-concentration impurity. The resistivity of the low-resistance P++ type substrate 1 is, for example, under 10 mΩcm. The high-resistance P− type epitaxial layer 2 is formed on the low-resistance P++ type substrate 1. The high-resistance P− type epitaxial layer 2 is, for example, composed of a low-resistance P− type monocrystalline silicon which includes a low-concentration impurity. The resistivity of the high-resistance P− type epitaxial layer 2 is, for example, 20 mΩcm. The low-resistance P++ type substrate 1 and the high-resistance P− type epitaxial layer 2 may be composed of GaAs, GaN or SiC.

The channel region 7 is a P type region. The channel region 7 is selectively formed at a part of an upper face of the high-resistance P− type epitaxial layer 2. The channel region 7 sets a proper threshold voltage of a transistor, and serves as a punch through stopper to restrain an extension of a depletion layer extending from the drain region 9 to the source region 5. The gate oxide film 4 and the gate electrode 3 are formed on the channel region 7 in order.

The source region 5 and the offset region 8 are formed above a part of the upper face of the high-resistance P− type epitaxial layer 2 so that the channel region 7 is between the source region 5 and the offset region 8. The source region 5 serves as a source electrode, and is a N++ type region including a high-concentration impurity. The offset region 8 is a N− type region including a low-concentration impurity. The channel region 7, the source region 5 and the offset region 8 are formed self-aligningly with the gate electrode 3. A part of the source region 5 and the offset region 8 are overlapped at the gate electrode 3. The drain region 9 is a N++ type region including a high-concentration impurity, serves as a drain electrode, and is arranged to be in touch with the offset region 8 and to be on the opposite side of the channel region 7.

The penetrating conductive region 6 is a P++ type region including a high-concentration impurity, and is a reach-through layer which is in touch with the source region 5 and is formed from the upper face of the high-resistance P− type epitaxial layer 2 to the low-resistance P++ type substrate 1. The source electrode 5a is formed for the purpose of connecting the source region 5 and the penetrating conductive region 6. The source electrode 5a contacts ohmically to both of the source region 5 and the penetrating conductive region 6. It is thus possible to use the low-resistance P++ type substrate 1 as a source electrode.

The insulating film 11 is formed so as to cover the high-resistance P− type epitaxial layer 2, the gate electrode 3 and the gate oxide film 4. The insulating film 11 is composed of an insulating material such as SiO₂. The thickness of the insulating film 11 is, for example, 0.5 μm. The drain electrode 9a is formed by forming an opening in an insulating film 11a covering the insulating film 11. In addition, another opening of the insulating film 11a is formed.

The screening electrode 10 is a thin-plate electrode composed of WSi, Au, Al or the like. The screening electrode 10 is formed between the gate electrode 3 and the drain region 9 in the insulating film 11 above the offset region 8. The screening electrode has a width of 0.2 μm, for example, in a direction between the gate electrode 3 and the drain electrode 9a. The distance between the screening electrode 10 and the offset region 8 is, for example, 0.2 μm. A material composing the screening electrode 10 is not limited and may be a conductive material. A polysilicon which can be used for a gate electrode of an ordinary MOS transistor may be used for the screening electrode 10. It is preferable that a polysilicon doped with boron, phosphorus or the like is used, if the polysilicon is used for the screening electrode 10. It is because the conductivity of the screening electrode 10 is improved. The form of the screening electrode 10 will be described later.

In the embodiment, the thin-plate screening electrode 10 is provided between the gate electrode 3 and the drain region 9. And the drain breakdown voltage is improved. The width of the screening electrode 10 in the direction between the gate electrode 3 and the drain electrode 9a is small. And it is possible to restrain the reduction of the drain current. It is thus possible to restrain the reduction of the drain current and to improve the drain breakdown voltage in the semiconductor device 100 in accordance with the embodiment.

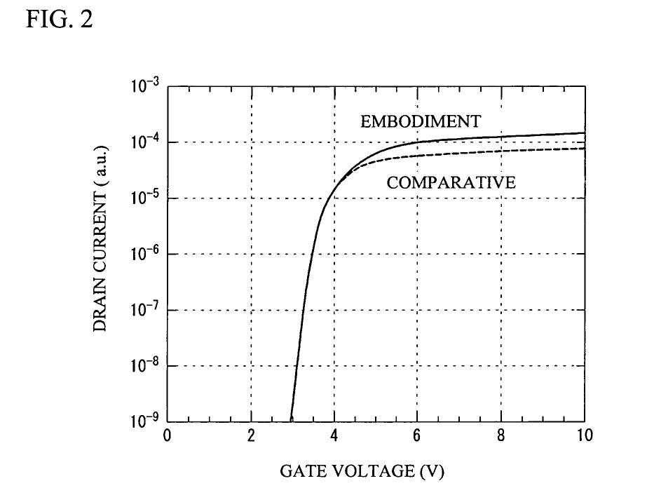

A description will be given of a relationship between the gate voltage and the drain current of the semiconductor device 100 in accordance with the embodiment. FIG. 2 illustrates a relationship between the gate voltage and the drain current. A vertical axis of FIG. 2 shows the drain current. A horizontal axis of FIG. 2 shows the drain voltage. A dot line in FIG. 2 shows a property of a conventional semiconductor device. A solid line in FIG. 2 shows a property of the semiconductor device 100 in accordance with the embodiment.

The conventional semiconductor device has a screening electrode between a gate electrode and a drain region. The width of the screening electrode in the direction between the gate electrode and the drain region is approximately 0.5 μm. The width of the screening electrode 10 in accordance with the embodiment in the direction between the gate electrode 3 and the drain electrode 9a is 0.1 μm.

As shown in FIG. 2, the drain current increases with the increase of the gate voltage in each of the semiconductor devices. The drain current of the semiconductor device in accordance with the embodiment increases by 75% relative to the conventional semiconductor device, when the gate voltage is 10V. It is thus confirmed that the reduction of the drain current is restrained if the width of the screening electrode 10 in the direction between the gate electrode and the drain electrode is reduced, as is the case of the semiconductor device 100.

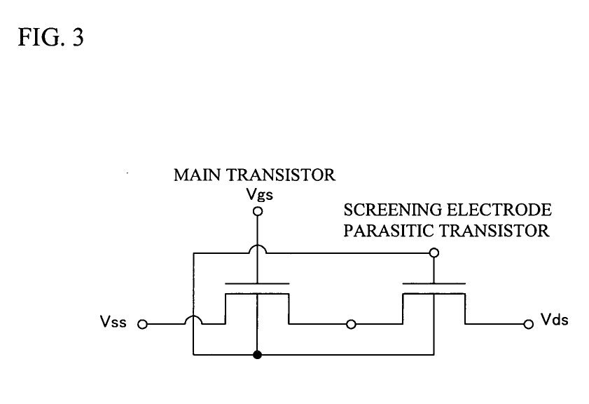

Next, a description will be given of a doctrine of the invention. FIG. 3 illustrates a circuit diagram to account for the effect of the screening electrode 10 referring to a MOS transistor. As shown in FIG. 3, it is possible to identify the screening electrode 10 as the MOS transistor. It is thus realized that an offset gate structure of a transistor having the screening electrode 10 is that in which another transistor is connected to a main transistor serially.

It is possible to identify the transistor in FIG. 3 as a depression type transistor, because the offset region 8 in FIG. 1 corresponding to a channel region is N− type. The electrical conductivity of the region is determined from the electrical potential of the screening electrode 10. Generally, the gate voltage is always 0 V, because the screening electrode 10 is earthed with the source region 5. The electrical potential of the screening electrode 10 is thus 0 V, too. And a depleted layer extends in the offset region 8, when the transistor is operated by applying a positive voltage to Vds. Accordingly, the electrical conductivity is reduced and a high-current operation ability of the whole transistor is reduced.

The current operation ability increases with the reduction of the gate length of the transistor, because the screening electrode 10 is identified as a transistor. In addition, it is possible to realize the high-drain breakdown voltage and the high-current operation ability when a transistor having an effectively short gate is structured only at a drain end where the screening electrode 10 is to be arranged, because the factor determining the drain breakdown voltage is the position of the drain end of the screening electrode 10.

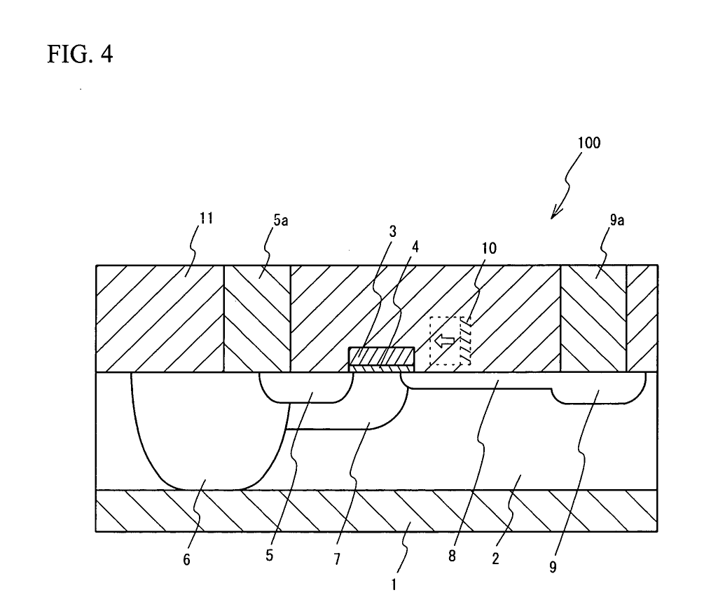

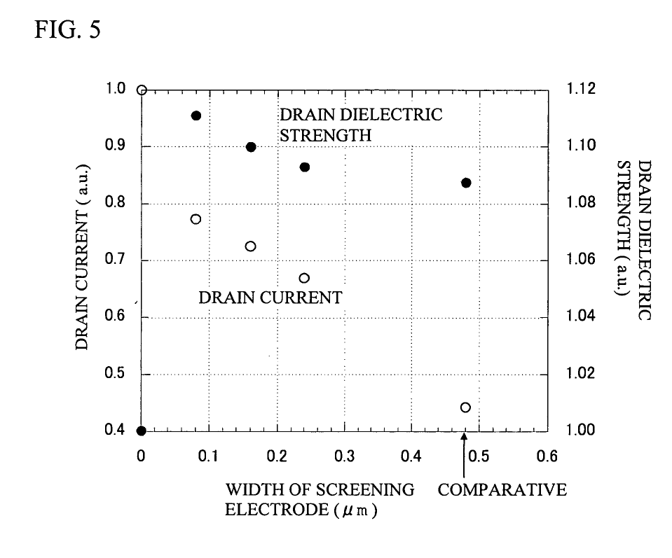

A description will be given of a change of the drain breakdown voltage and the drain current when the position of the drain end of the screening electrode 10 is fixed and the width of the screening electrode 10 between the gate electrode 3 and the drain electrode 9a changes. FIG. 4 illustrates a partly omitted schematic cross sectional view of the semiconductor device 100. As shown in FIG. 4, the drain breakdown voltage and the drain current is calculated when the width of the screening electrode 10 between the gate electrode 3 and the drain electrode 9a is changed. A position at the drain region 9 side of the screening electrode 10 is fixed and the distance between the position and the gate electrode 3 is 0.6 μm. The width of the screening electrode 10 between the gate electrode 3 and the drain electrode 9a is changed from 0 μm (a case where the gate electrode does not exists) to 0.5 μm. The result is shown in FIG. 5.

FIG. 5 illustrates a relationship between the width of the screening electrode 10 between the gate electrode 3 and the drain electrode 9a, and the drain current and the drain breakdown voltage. The left vertical axis of FIG. 5 shows the drain current. The right vertical axis of FIG. 5 shows the drain breakdown voltage. Both of the values are standardized with a value in a case where the screening electrode 10 does not exist (the width of the screening electrode 10 is 0 μm). The horizontal axis of FIG. 5 shows the width of the screening electrode 10 between the gate electrode 3 and the drain electrode 9a.

As shown in FIG. 5, the drain current is reduced with the increase of the width of the screening electrode 10 between the gate electrode 3 and the drain electrode 9a. The drain current of the conventional semiconductor device is reduced by 50% relative to a case where the screening electrode 10 does not exist. The drain breakdown voltage increases by approximately 10% relative to a case where the screening electrode 10 does not exist (the width of the screening electrode 10 is 0 μm), because the screening electrode 10 exists. However, the drain breakdown voltage changes slowly relative to the width of the screening electrode 10. The drain breakdown voltage is nearly constant when the position of the drain end of the screening electrode 10.

It is therefore preferable that the width of the screening electrode 10 between the gate electrode 3 and the drain electrode 9a is under 0.3 μm in order to restrain the reduction of the drain current and to improve the drain breakdown voltage. It is still preferable that the width of the screening electrode 10 between the gate electrode 3 and the drain electrode 9a is under 0.2 μm. In addition, it is preferable that the width of the screening electrode 10 between the gate electrode 3 and the drain electrode 9a is 0.01 μm to 0.3 μm. It is still preferable that the width of the screening electrode 10 between the gate electrode 3 and the drain electrode 9a is 0.01 μm to 0.2 μm.

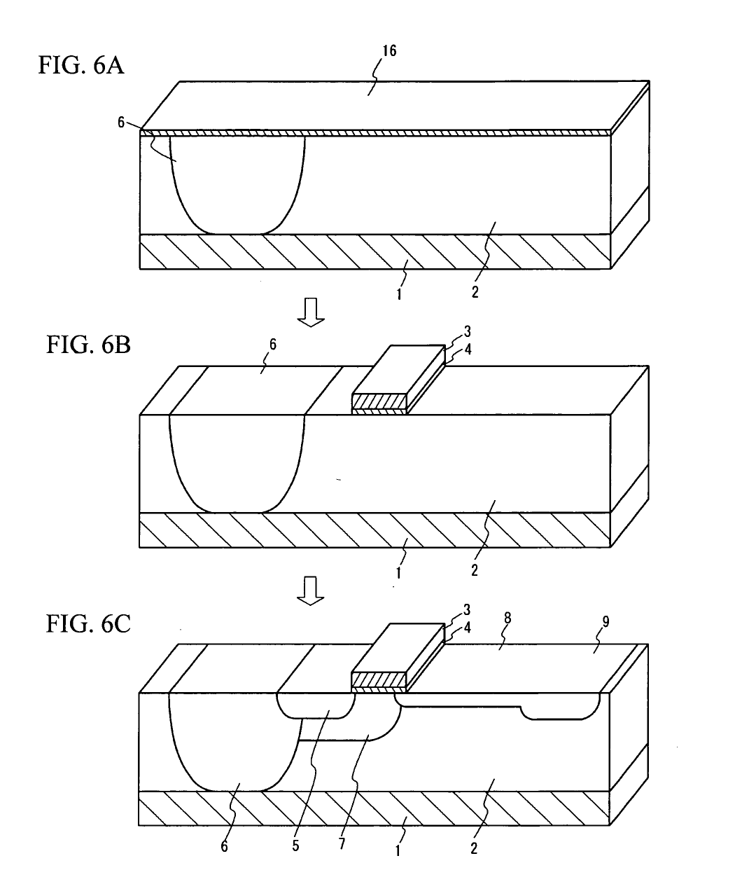

Next, a description will be given of a fabrication method of the semiconductor device 100. FIG. 6A through FIG. 8C illustrate a process flow diagram accounting for the fabrication method of the semiconductor device 100. At first, a substrate, in which the high-resistance P− type epitaxial layer 2 is formed on the low-resistance P++ type substrate 1, is provided. The penetrating conductive region 6 is formed in the substrate. In this case, a thermally oxidized film 16, whose thickness is 50 Å, is formed on the high-resistance P− type epitaxial layer 2 in advance. A resist mask pattern is formed above the high-resistance P− type epitaxial layer 2 except for an area where the penetrating conductive region 6 is to be formed. A p− type impurity (boron, for example) is doped in a part of the high-resistance P− type epitaxial layer 2 whose upper face is not covered with the resist mask pattern, by an ion implantation method. And it is possible to form the penetrating conductive region 6 by thermally treating the area where the ion implantation is treated.

Next, the gate oxide film 4 and a tungsten polycide layer corresponding to the gate electrode 3 are formed on the high-resistance P− type epitaxial layer 2 at interval from the penetrating conductive region 6 by CVD method, as shown in FIG. 6B. After that, a resist mask pattern is formed except for an area where the gate electrode 3 is to be formed. The gate electrode 3 is formed by RIE method. After that, the resist mask pattern is eliminated.

Then, the channel region 7, the offset region 8, the source region 5 and the drain region 9 are formed in order, as shown in FIG. 6C. An opening of a resist mask pattern is formed above the source region 5 side of the gate electrode 3. A P− type impurity (boron, for example) is doped in the high-resistance P− type epitaxial layer 2 through the opening of the resist mask pattern by the ion implantation method. The resist mask pattern is eliminated. After that, the channel region 7 is formed by thermally treating the area at 1000 degree C. In this case, the drain end side of the opening of the resist mask pattern is above the gate electrode 3, and the gate electrode 3 serves as a part of an injection mask. And it is possible to form the channel region 7 self-aligningly. It is thus possible to implant ions to the source region 5 side end of the gate electrode 3 when the size of the resist mask pattern changes in a measure, if the drain end side of the opening of the resist mask pattern is above the gate electrode 3. It is thus possible to form the stable channel region 7.

An N− type impurity (a phosphorus, for example) is implanted into the high-resistance P− type epitaxial layer 2 by the ion implantation method. And the offset region 8 is formed self-alligningly with the gate electrode 3.

A resist mask pattern is formed so as to cover a part of the offset region 8. An N− type impurity (arsenic, for example) is doped into the high-resistance P− type epitaxial layer 2 through an opening of the resist mask pattern by the ion implantation method. And the source region 5 and the drain region 9 are formed. After that, the resist mask pattern is eliminated.

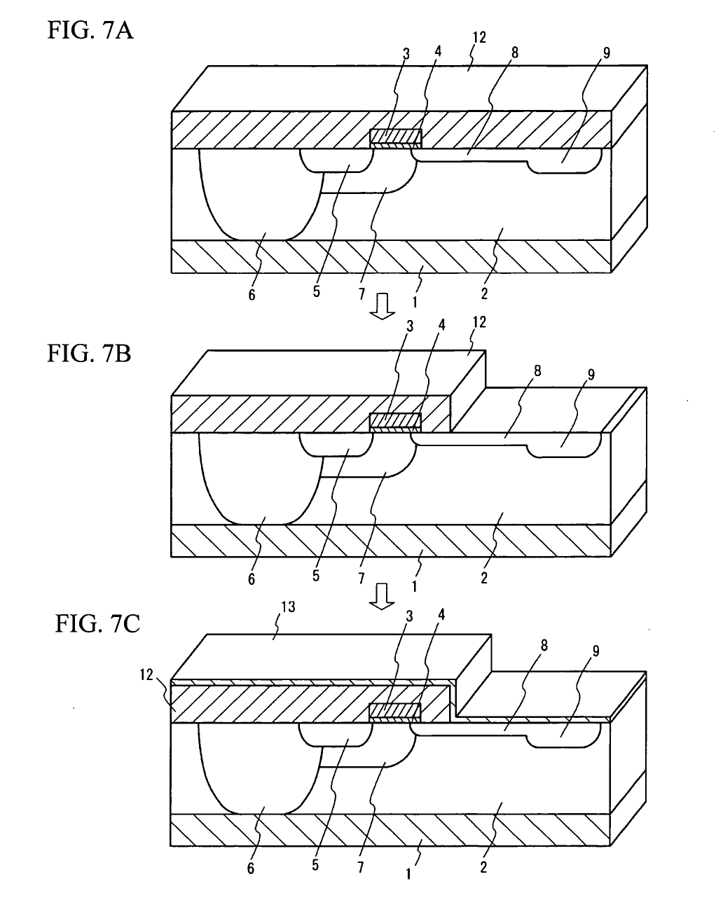

Next, an interlayer insulating film 12 composed of insulator such as SiO₂ is formed so as to cover the high-resistance P− type epitaxial layer 2, the gate oxide film 4 and the gate electrode 3, as shown in FIG. 7A. Then, a part of the offset region 8 at the drain region 9 side and the interlayer insulating film 12 on the drain region 9 are eliminated by etching. And a step is formed, as shown in FIG. 7B.

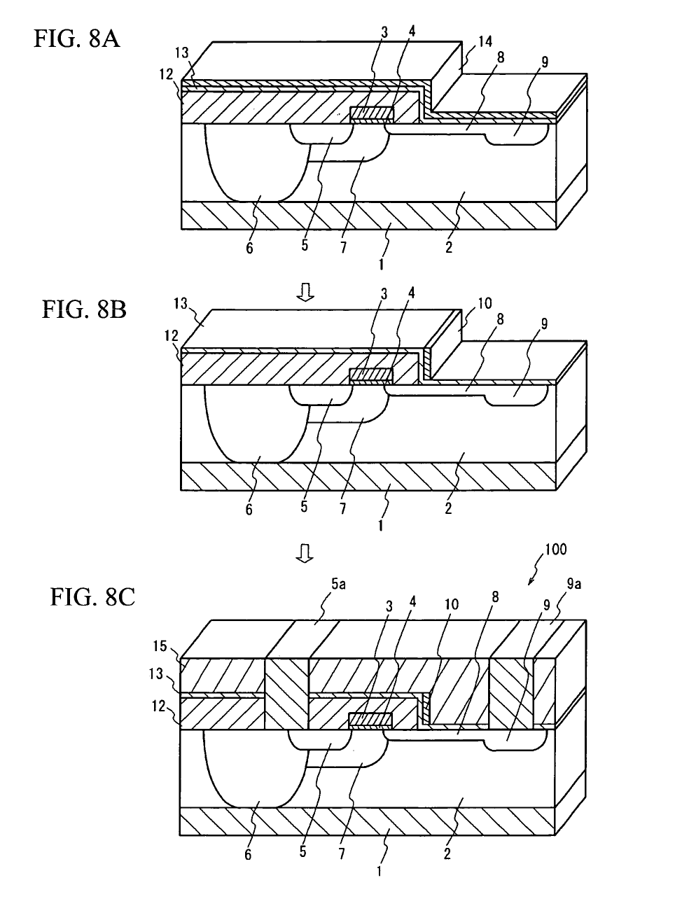

Next, an insulating film 13 is formed so as to cover the interlayer insulating film 12, the offset region 8 and the drain region 9, as shown in FIG. 7C. The interlayer insulating film 12 and the insulating film 13 form the insulating film 11. Then, an electrode layer 14 composed of a metal such as WSi, Au or the like or a polysilicon is formed on the insulating film 13 by CVD method, as shown in FIG. 8A. The thickness of the electrode layer 14 is, for example, 0.2 μm. It is preferable to dope boron, phosphorus or the like into the electrode layer 14 by in-situ doping method when the electrode layer 14 is formed of polysilicon.

Next, anisotropic etching is treated to the electrode layer 14, as shown in FIG. 8B. The screening electrode 10 is thus formed. In the fabrication method of the semiconductor device 100 in accordance with the embodiment, sidewall film forming method is used when the screening electrode 10 is formed. And it is possible to control the width of the screening electrode 10 between the gate electrode 3 and the drain electrode 9a, by controlling the thickness of the electrode layer 14 formed in the step shown in FIG. 8A. It is thus easy to control the width of the screening electrode 10 between the gate electrode 3 and the drain electrode 9a.

Then, an insulating film 15 is formed on the insulating film 13, as shown in FIG. 8C. Openings are formed in the interlayer insulating film 12, the insulating film 13 and the insulating film 15 on the source region 5 and the drain region 9. And the source electrode 5a and the drain electrode 9a are formed in the openings. In addition, the screening electrode 10 is connected to an earthed electrode (not illustrated in FIG. 8C).

In the embodiment, the screening electrode 10 corresponds to the electrode part.

### Second Embodiment

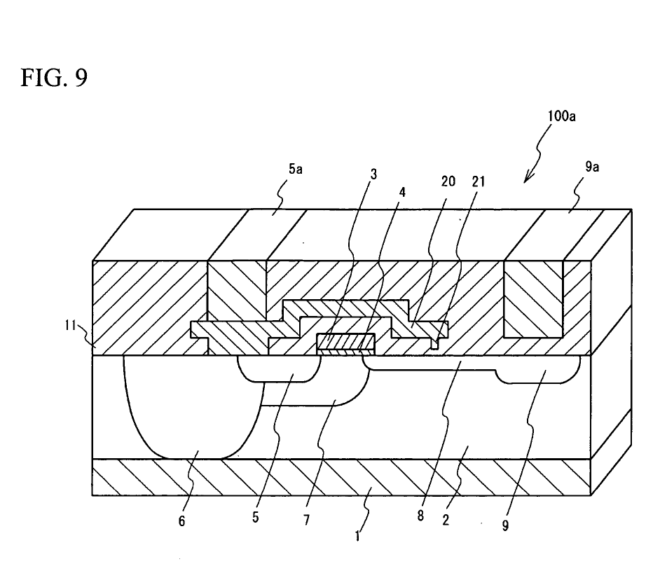

FIG. 9 illustrates a partly omitted perspective view of a semiconductor device 100a in accordance with a second embodiment. A different point of the semiconductor device 100a from the semiconductor device 100 is a point that a source wall 20 is formed instead of the screening electrode 10. The source wall 20 is earthed. The end of the source wall 20 at the drain electrode 9a side is positioned between the gate electrode 3 and the drain electrode 9a. The embodiment has an objective to improve the high frequency property by cutting the capacitance coupling between the gate electrode 3 and the drain electrode 9a.

The source wall 20 is earthed and the end of the source wall 20 at the drain electrode 9a side is positioned between the gate electrode 3 and the drain electrode 9a. And the corresponding effect of the screening electrode 10 mentioned above is exerted, even if the source wall 20 has an objective to serve as a source wall. It is thus significant to adopt the structure of the embodiment. The source wall 20 is composed of an electrically conductive material such as a metal like WSi Au or the like or a polysilicon.

The source wall 20 extends from the source region 5 to a position above the offset region 8 and between the gate electrode 3 and the drain region 9, passing above the gate electrode 3. The end of the source wall 20 is formed to be thin plate and projects toward the offset region 8. The projecting part is called a projecting part 21 hereinafter. In the embodiment, the projecting part 21 serves as the screening electrode 10.

It is preferable that the width of the projecting part 21 between the gate electrode 3 and the drain electrode 9a is under 0.3 μm. It is still preferable that the width of the projecting part 21 between the gate electrode 3 and the drain electrode 9a is under 0.2 μm. In addition, it is preferable that the width of the projecting part 21 between the gate electrode 3 and the drain electrode 9a is 0.01 μm to 0.3 μm. It is still preferable that the width of the projecting part 21 between the gate electrode 3 and the drain electrode 9a is 0.02 μm to 0.2 μm. The interval between the projecting part 21 and the offset region 8 is, for example, 0.2 μm.

The drain electrode 9a is formed in an opening of the insulating film 11 covering the source wall 20. In this case, another opening exposing a part of the source wall 20 is formed at a time. The source electrode 5a is formed so as to be connected to the exposed part of the source wall 20. There may be provided a part connecting the source electrode 5a to the source region 5 and the penetrating conductive region 6 without source wall as in a case of FIG. 1, although it is not illustrated in FIG. 9.

In the embodiment, the thin plate projecting part 21 is formed between the gate electrode 3 and the drain region 9. And the drain breakdown voltage is improved. In addition, the width of the projecting part 21 between the gate electrode 3 and the drain electrode 9a is small. And it is possible to restrain the reduction of the drain current. It is thus possible to restrain the reduction of the drain current and to improve the drain breakdown voltage in the semiconductor device 100a in accordance with the embodiment. In addition, the high frequency property of the semiconductor device 100a is improved if the source wall 20 is provided instead of the screening electrode 10.

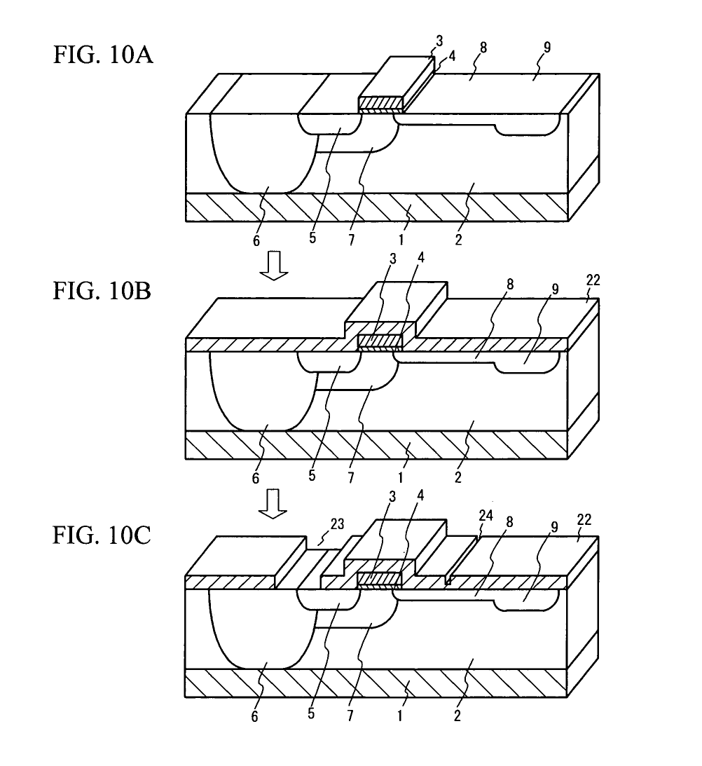

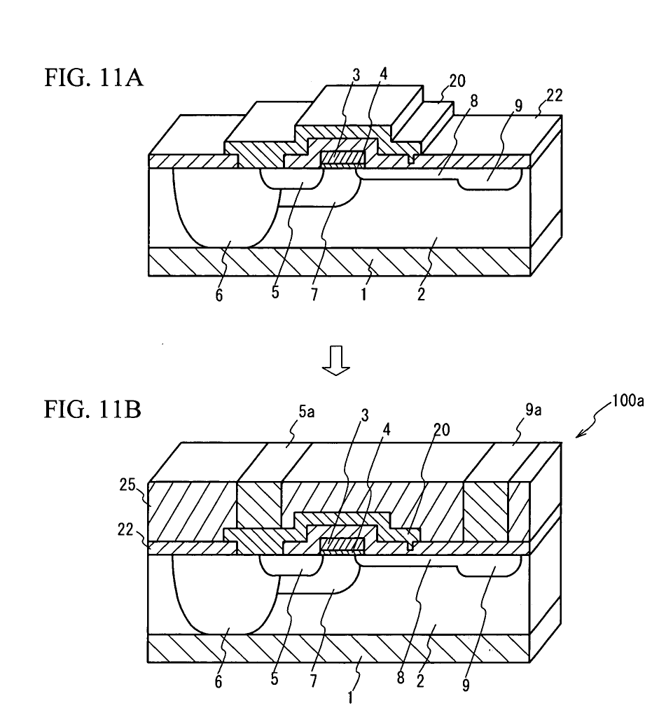

Next, a description will be given of a fabrication method of the semiconductor device 100a. FIG. 10A through FIG. 11B illustrate a process flow diagram to account for the fabrication method of the semiconductor device 100a. As shown in FIG. 10A, the semiconductor device shown in FIG. 6C is provided. Next, an interlayer insulating film 22 composed of an insulating material such as SiO₂ is formed so as to cover the high-resistance P− type epitaxial layer 2, the gate oxide film 4 and the gate electrode 3, as shown in FIG. 10B.

Then, an opening 23 is formed in a part of the source region 5, as shown in FIG. 10C. In this case, a resist mask pattern is formed so as to cover the interlayer insulating film 22 except for an area on a part of the source region 5 and on a part of the penetrating conductive region 6. The interlayer insulating film 22 where the resist mask pattern does not cover is eliminated by etching. And the opening 23 is formed. Next, a groove-like opening 24 is formed at the interlayer insulating film 22 between the gate electrode 3 and the drain region 9. In this case, a resist mask pattern is formed so as to cover the interlayer insulating film 22 except for a part on a part between the gate electrode 3 and the drain region 9. The interlayer insulating film 22 where the resist mask pattern does not cover is eliminated by etching. And the opening 24 is formed. After that, the resist mask pattern is eliminated.

Next, the source wall 20 is formed, as shown in FIG. 11A. In this case, Au, WSi, Al or the like whose thickness is approximately 0.3 μm is formed by vacuum deposition method, sputtering method, CVD method or the like. A resist pattern is formed so as to cover except for a part of the interlayer insulating film 22 where the source wall 20 is to be formed. Au, WSi, Al or the like of the interlayer insulating film 22 where the resist mask pattern is not formed is eliminated by etching. And the source wall 20 is formed. It is preferable to dope boron, phosphorus or the like into the source wall 20 by in-situ doping method when the source wall 20 is formed of polysilicon.

Then, after forming an insulating film 25 covering the source wall 20, openings are formed in parts of the insulating film 25. The drain electrode 9a and the source electrode 5a connecting to a part of the source wall 20 are formed in the openings. Accordingly, the semiconductor device 100a is fabricated.

### Third Embodiment

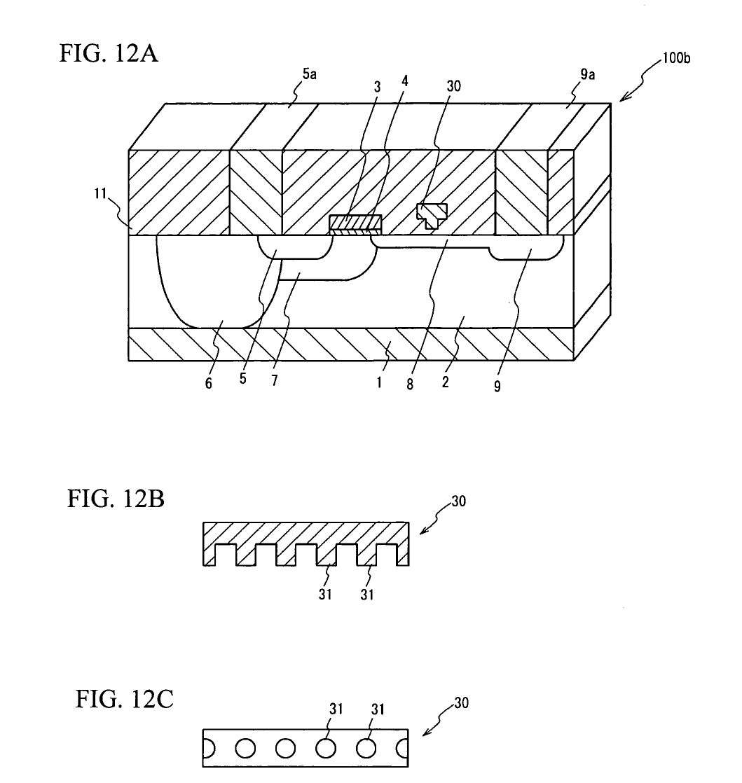

FIG. 12A through FIG. 12C illustrate a semiconductor device 100b in accordance with a third embodiment. FIG. 12A illustrates a partly omitted perspective view of the semiconductor device 100b. A different point of the semiconductor device 100b from the semiconductor device 100 is a point that a comb electrode 30 is provided instead of the screening electrode 10.

The comb electrode 30 is a comb type electrode composed of a metal such as WSi, Au or the like or an electrically conductive material such as polysilicon. The comb electrode 30 is formed above the offset region 8 and between the gate electrode 3 and the drain region 9, in the insulating film 11. The source electrode 5a and the drain electrode 9a are formed in openings of the insulating film 11 covering the comb electrode 30.

FIG. 12B illustrates a cross sectional view in a case where the comb electrode 30 is cut along a direction in which the gate electrode 3 extends. As shown in FIG. 12B, the comb electrode 30 has comb teeth 31. An interval between each of the comb teeth 31 is approximately 0.2 μm. FIG. 12C illustrates a bottom view of the comb electrode 30. As shown in FIG. 12C, each of the comb teeth 31 has a cylinder shape. The diameter of the comb teeth 31 is approximately 0.2 μm.

The comb electrode 30 is formed between the gate electrode 3 and the drain electrode 9a. And it is possible to bias the offset region 8 partly. Therefore, the comb electrode 30 causes the improvement of the drain breakdown voltage, even if the comb teeth 31 are formed at intervals. In addition, the diameter of the comb teeth 31 is small. And it is possible to restrain the reduction of the drain current. Further, there is no electrode between each of the comb teeth 31. And it is possible to restrain the reduction of the drain current more effectively relative to the semiconductor device 100.

The form of the comb teeth 31 is not limited. The comb teeth 31 may have a cylinder shape or a rectangular column shape. The comb teeth 31 may project toward the high-resistance P− type epitaxial layer 2. There may be dispersion between the lengths of the comb teeth 31. It is preferable that the lengths of the comb teeth 31 are equal. There may be dispersion between the intervals of the comb teeth 31. It is preferable that the intervals of the comb teeth 31 are equal. This is because the drain breakdown voltage is improved if the lengths of the comb teeth 31 and the intervals of the comb teeth 31 are equal.

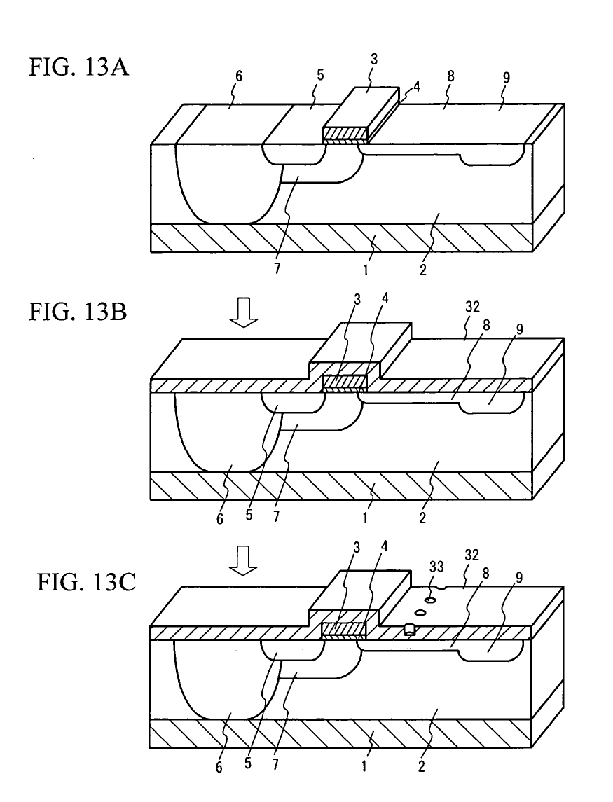

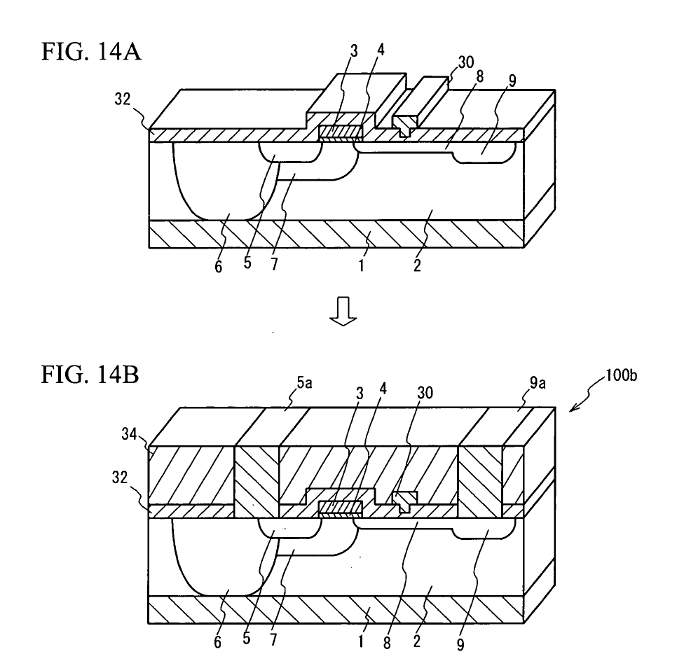

Next, a description will be given of a fabrication method of the semiconductor device 10b. FIG. 13A through FIG. 14B illustrate a process flow diagram to account for the fabrication method of the semiconductor device 100b. At first, the semiconductor device shown in FIG. 6C is provided, as shown in FIG. 13A. Then, an interlayer insulating film 32 is formed so as to cover the high-resistance P− type epitaxial layer 2, the gate oxide film 4 and the gate electrode 3.

Next, openings 33 having a cylinder shape are formed in the interlayer insulating film 32 between the gate electrode 3 and the drain region 9. In this case, openings are formed in a resist mask pattern above a part of the interlayer insulating film 32 where the comb teeth 31 are to be formed. The parts of the interlayer insulating film 32 where the resist mask pattern is not formed are eliminated by etching. And the openings 33 are formed. After that, the resist mask pattern is eliminated.

Next, the comb electrode 30 is formed, as shown in FIG. 14A. In this case, Au, WSi, Al or the like is formed on the whole interlayer insulating film 32 by sputtering method, CVD method or the like. A resist pattern is formed at an area where the comb electrode 30 is to be formed. Au, WSi, Al or the like of the interlayer insulating film 32 where the resist mask pattern is not formed is eliminated by etching. And the comb electrode 30 is formed. It is preferable to dope boron, phosphorus or the like into the comb electrode 30 by in-situ doping method when the comb electrode 30 is formed of polysilicon.

Then, an insulating film 34 is formed on the interlayer insulating film 32. Openings are formed at the interlayer insulating film 32 and the insulating film 34 on the source region 5 and the drain region 9. The source electrode 5a and the drain electrode 9a are formed in the openings. In addition, the comb electrode 30 is connected to an earthed electrode, although the electrode is not illustrated in FIG. 14B.

### Fourth Embodiment

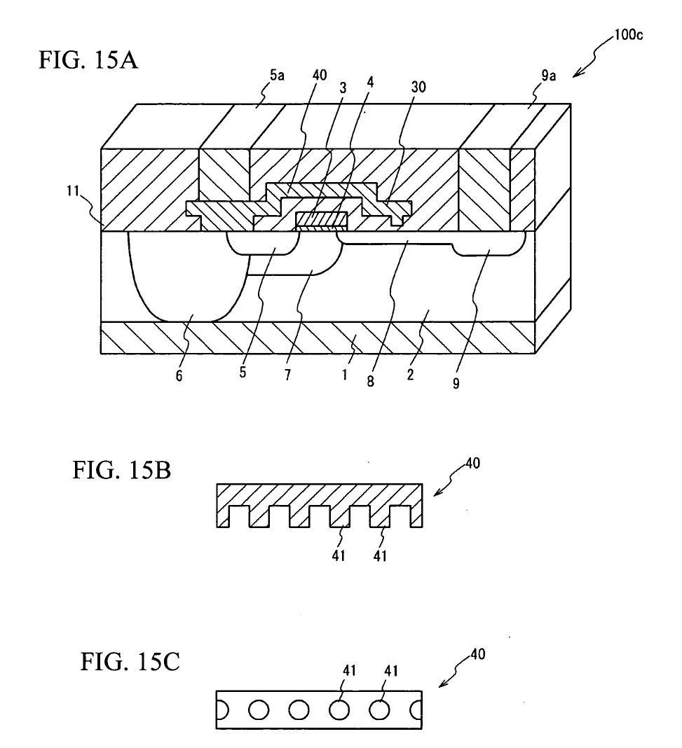

FIG. 15A through FIG. 15C illustrate a semiconductor device 100c in accordance with a fourth embodiment. FIG. 15A illustrates a partly omitted perspective view of the semiconductor device 100c. A different point of the semiconductor device 100c from the semiconductor device 100 is a point that a source wall 40 is formed instead of the screening electrode 10. The source wall 40 is composed of a metal such as WSi, Au or the like or an electrically conductive material such as polysilicon, similarly to the screening electrode 10. The source electrode 5a and the drain electrode 9a are formed in openings of an insulating film covering the source wall 40. A part of the source wall 40 is exposed. And the source electrode 5a connected to the part of the source wall 40 is formed.

The source wall 40 extends from the source region 5 to a position above the offset region 8 and between the gate electrode 3 and the drain region 9, passing above the gate electrode 3. In the embodiment, an end of the source wall 40 serves as the screening electrode 10 shown in FIG. 1.

FIG. 15B illustrates a cross sectional view in a case where the end of the source wall 40 at the drain region 9 side is cut along a direction in which the gate electrode 3 extends. As shown in FIG. 15B, the source wall 40 has comb teeth 41. The comb teeth 41 project toward the offset region 8. An interval between each of the comb teeth 41 is approximately 0.2 μm.

FIG. 15C illustrates a bottom view of the front part of the source wall 40. As shown in FIG. 15C, each of the comb teeth 41 has a cylinder shape. The diameter of the comb tooth 41 is approximately 0.2 μm.

The source wall 40 extends to the position between the gate electrode 3 and the drain region 9. And it is possible to bias the offset region 8 partly. Therefore, the source wall 40 causes the improvement of the drain breakdown voltage of the semiconductor device 100c, even if the comb teeth 41 are formed at intervals at the end of the source wall 40. In addition, the diameter of the comb teeth 41 is small. And it is possible to restrain the reduction of the drain current. Further, there provided no electrode between each of the comb teeth 41. And it is possible to restrain the reduction of the drain current more effectively relative to the semiconductor device 100 in accordance with the first embodiment. The high frequency property of the semiconductor 100c is improved, because the source wall 40 is provided instead of the screening electrode 10.

The form of the comb teeth 41 is not limited. The comb teeth 41 may have a cylinder shape or a rectangular column shape. The comb teeth 41 may project toward the offset region 8. There may be dispersion between the lengths of the comb teeth 41. It is preferable that the lengths of the comb teeth 41 are equal. There may be dispersion between the intervals of the comb teeth 41. It is preferable that the intervals of the comb teeth 41 are equal. This is because the drain breakdown voltage is improved if the lengths of the comb teeth 41 and the intervals of the comb teeth 41 are equal.

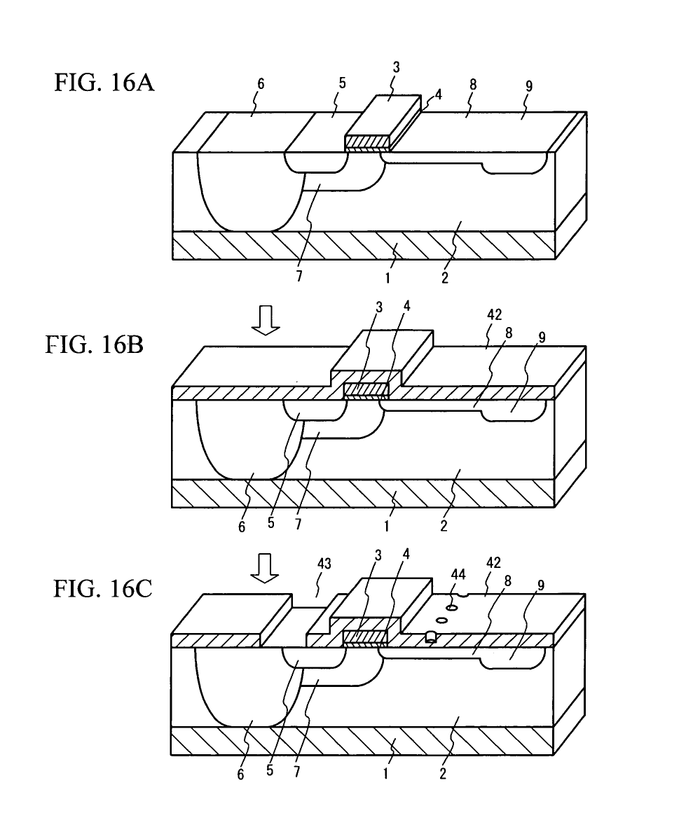

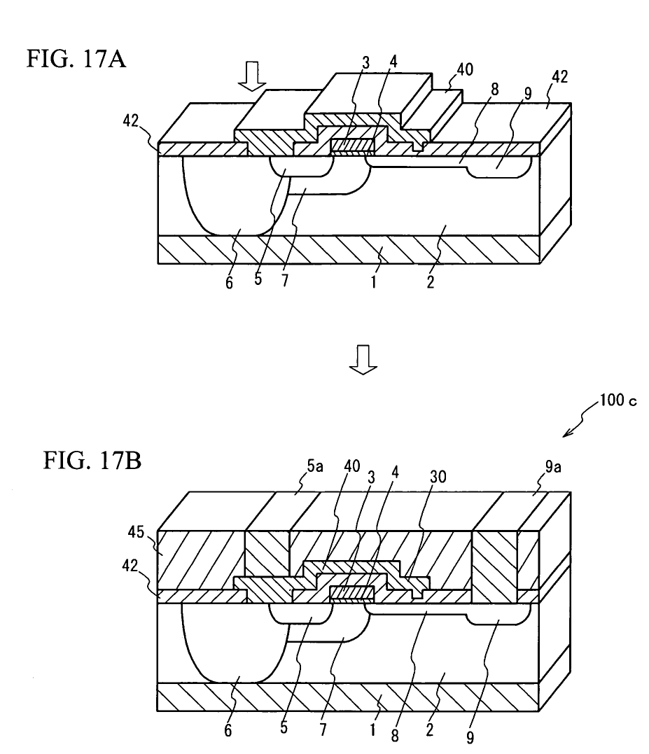

Next, a description will be given of a fabrication method of the semiconductor device 100c. FIG. 16A through FIG. 17B illustrate a process flow diagram to account for the fabrication method of the semiconductor device 100c. At first, the semiconductor device shown in FIG. 6C is provided, as shown in FIG. 16A. Then, an interlayer insulating film 42 is formed so as to cover the high-resistance P− type epitaxial layer 2, the gate oxide film 4 and the gate electrode 3.

Then, an opening 43 is formed in a part of the source region 5 and in a part of the penetrating conductive region 6. In this case, a resist mask pattern covers a part of the interlayer insulating film 42 except for an area on the source region 5. The interlayer insulating film 42 where the resist mask pattern does not cover is eliminated by etching. And the opening 43 is formed.

Next, an opening 43 having a cylinder shape is formed in the interlayer insulating film 42 between the gate electrode 3 and the drain region 9. In this case, a resist mask pattern covers a part of the interlayer insulating film 42 except for areas where the comb teeth 41 are to be formed. The areas of the interlayer insulating film 42 where the resist mask pattern is not formed are eliminated by etching. And the opening 43 is formed. After that, the resist mask pattern is eliminated.

Next, the source wall 40 is formed, as shown in FIG. 17A. In this case, Au, WSi, Al or the like is formed on the whole interlayer insulating film 42 by sputtering method, CVD method or the like. A resist mask pattern is formed above an area where the source wall 40 is to be formed. Au, WSi, Al or the like of the interlayer insulating film 42 where the resist mask pattern is not formed is eliminated by etching. And the source wall 40 is formed. It is preferable to dope boron, phosphorus or the like into the source wall 40 by in-situ doping method when the source wall 40 is formed of polysilicon.

Then, an insulating film 45 covering the source wall 40 is formed. After that, openings are formed in the interlayer insulating film 45. The drain electrode 9a and the source electrode 5a to be connected to a part of the source wall 40 are formed in the openings. Accordingly, the semiconductor device 100c is fabricated.

As mentioned above, SI-LDMOS (Laterally Diffused MOS) is described as the semiconductor devices 100, 100a, 100b, and 100c. However, a GaAs-based FET, a Si-based FET or a GaN-based FET can be adopted for the semiconductor devices 100, 100a, 100b, and 100c.

While the above description constitutes the preferred embodiments of the present invention, it will be appreciated that the invention is susceptible of modification, variation and change without departing from the proper scope and fair meaning of the accompanying claims.

The present invention is based on Japanese Patent Application No. 2005-105162 filed on Mar. 31, 2005, the entire disclosure of which is hereby incorporated by reference.

What is claimed is:

1. A semiconductor device comprising:
a gate electrode formed above a semiconductor layer;
a source electrode and a drain electrode formed on the semiconductor layer, the gate electrode being located between the source electrode and the drain electrode; and
an electrode part that is provided between the gate electrode and the drain electrode and has a width of 10 nm to 300 nm in a direction between the gate electrode and the drain electrode.

2. A semiconductor device comprising:
a gate electrode formed above a semiconductor layer;
a source electrode and a drain electrode formed on the semiconductor layer, the gate electrode being located between the source electrode and the drain electrode; and
a source wall that extends from the source electrode to between the gate electrode and the drain electrode, passing above the gate electrode,
the source wall including an end part having a width of 10 nm to 300 nm in a direction between the gate electrode and the drain electrode.

3. A semiconductor device comprising:
a gate electrode formed above a semiconductor layer;
a source electrode and a drain electrode formed on the semiconductor layer, the gate electrode being located between the source electrode and the drain electrode; and
an electrode part that is provided between the gate electrode and the drain electrode, extends in a gate width direction, and has comb teeth extending toward the semiconductor layer.

4. A semiconductor device, comprising:
a gate electrode formed above a semiconductor layer;
a source electrode and a drain electrode formed on the semiconductor layer, the gate electrode being located between the source electrode and the drain electrode; and
a source wall that extends from the source electrode to between the gate electrode and the drain electrode, passing above the gate electrode,
the source wall having an end part that extends in a gate width direction and has comb teeth extending toward the semiconductor layer.

5. The semiconductor device as claimed in claim 1, wherein the electrode part is composed of one of WSi, Au and polysilicon.

6. The semiconductor device as claimed in claim 2, wherein the source wall is composed of one of WSi, Au and polysilicon.

7. The semiconductor device as claimed in claim 1, wherein the semiconductor device is one of LDMOS, GaAs-based FET, Si-based FET and GaN-based FET.

8. The semiconductor device as claimed in claim 1, wherein the semiconductor layer is composed of one of Si, SiC, GaAs, and GaN-based.

9. A fabrication method of a semiconductor device comprising:
forming a gate electrode above a semiconductor layer so as to be interposed between a source region and a drain region of the semiconductor layer;
forming an insulating layer covering the semiconductor layer and the gate electrode; and
forming an electrode part on the insulating layer between the drain region and the gate electrode and the electrode part has a width of 10 nm to 300 nm in a direction between the gate electrode and the drain region.

10. The fabrication method as claimed in claim 9, wherein the step of forming the electrode part comprises forming a step by etching a part of the insulating layer, forming a second insulating layer on the insulating layer, forming an electrode on the whole second insulating layer, and eliminating the electrode except for a part on a side wall of the step by etching.

11. A fabrication method of a semiconductor device comprising:
forming a gate electrode above a semiconductor layer so as to be interposed between a source region and a drain region of the semiconductor layer;
forming an insulating layer covering the semiconductor layer and the gate electrode;
exposing the source region; and
forming a source wall so that the source wall extends from the source region to between the gate electrode and the drain region passing above the gate electrode, and the source wall includes an end part having a width of 10 nm to 300 nm in a direction between the gate electrode and the drain region.

12. The fabrication method as claimed in claim 11, wherein the step of forming the source wall comprises forming a concave portion in the insulating layer between the gate electrode and the drain region by etching, and forming the end part so that a part of the source wall remains in the concave portion.

13. A fabrication method of a semiconductor device comprising:
forming a gate electrode above a semiconductor layer so as to be interposed between a source region and a drain region of the semiconductor layer;
forming an insulating layer covering the semiconductor layer and the gate electrode; and
forming an electrode part on the insulating layer between the drain region and the gate electrode,
wherein the electrode part has an end part that extends in a direction in which the gate electrode extends, and has comb teeth extending toward the semiconductor layer.

14. The fabrication method as claimed in claim 13, wherein the step of forming the electrode part comprises forming openings in the insulating layer between the gate electrode and the drain region in a direction in which the gate electrode extends, and forming the electrode part in the openings.

15. A fabrication method of a semiconductor device comprising:
forming a gate electrode above a semiconductor layer so as to be interposed between a source region and a drain region of the semiconductor layer;
forming an insulating layer covering the semiconductor layer and the gate electrode;
exposing the source region; and
forming a source wall so that the source wall extends from the source region to between the gate electrode and the drain region, passing above the gate electrode, and the source wall has an end part that extends in a direction in which the gate electrode extends, and has comb teeth extending toward the semiconductor layer.

16. The fabrication method as claimed in claim 15, wherein the step of forming the source wall comprises forming openings in the insulating layer between the gate electrode and the drain region in a direction in which the gate electrode extends, and forming the source wall from an exposed part of the source region to the openings.

17. The fabrication method as claimed in claim 9, wherein the electrode part is composed of one of WSi, Au, Al and polysilicon.

18. The fabrication method as claimed in claim 11, wherein source wall is composed of one of WSi, Au, Al and polysilicon.

19. The fabrication method as claimed in claim 9, wherein the electrode part is formed by vacuum deposition method, sputtering method or CVD method.

20. The fabrication method as claimed in claim 11, wherein the source wall is formed by vacuum deposition method, sputtering method or CVD method.
